(19) United States
(12) Patent Application Publication
(10) Pub. No.: US 2026/0007048 A1
(43) Pub. Date: Jan. 1, 2026

(54) DISPLAY DEVICE AND METHOD OF MANUFACTURING THE SAME

(71) Applicant: Samsung Display Co., LTD., Yongin-si (KR)

(72) Inventor: Joonyung JANG, Yongin-si (KR)

(21) Appl. No.: 19/250,603

(22) Filed: Jun. 26, 2025

(30) Foreign Application Priority Data
Jun. 26, 2024 (KR) 10-2024-0083977
Jul. 11, 2024 (KR) 10-2024-0091821

(51) Int. Cl. H10K 59/80; H10K 59/12

(52) U.S. Cl. CPC H10K 59/877; H10K 59/1201

(57) ABSTRACT

A display device includes a substrate and a light control layer disposed on the substrate and including a light-scattering portion and a light-transmitting portion, where a surface roughness of the light-scattering portion is less than about 10 μm.

This application claims priority to Korean Patent Application No. 10-2024-0083977, filed on Jun. 26, 2024, and Korean Patent Application No. 10-2024-0091821, filed on Jul. 11, 2024, and all the benefits accruing therefrom under 35 U.S.C. § 119, the contents of which in their entireties are herein incorporated by reference.

### BACKGROUND

### 1. Field

One or more embodiments relate to a display device and a method of manufacturing the display device.

### 2. Description of the Related Art

A display device visually displays data. A display device may provide images using light-emitting diodes. Recently, various types of display devices are widely used in various fields, and various designs to improve the quality of display devices are being attempted.

### SUMMARY

One or more embodiments include a display device and a method of manufacturing the display device.

According to one or more embodiments, a display device includes a substrate and a light control layer disposed on the substrate and including a light-scattering portion and a light-transmitting portion, where the surface roughness of the light-scattering portion is less than about 10 micrometers (μm).

In an embodiment, the light-scattering portion may be provided in plural.

In an embodiment, the light-transmitting portion may be provided in plural.

In an embodiment, a plurality of light-scattering portions may be arranged at regular intervals in a plan view.

In an embodiment, the light-transmitting portion may include silicon dioxide (SiO₂).

In an embodiment, a maximum diameter of fine fragments included in the light-scattering portion may be less than about 10 μm.

In an embodiment, the light-scattering portion is defined by a portion of a glass onto which a pulse laser is radiated, and a width of the light-scattering portion may be equal to a diameter of a beam of the pulse laser.

In an embodiment, a ratio of a width of the light-transmitting portion to a sum of the width of the light-transmitting portion and the width of the light-scattering portion may be about 95% or greater.

In an embodiment, a ratio of the width of the light-scattering portion to a height of the light-scattering portion may be about 1/100 or less.

In an embodiment, light incident on the light-scattering portion may be Mie scattered by the fine fragments included in the light-scattering portion.

According to one or more embodiments, a method of manufacturing a display device includes preparing a glass and irradiating the glass with a pulse laser to form a light control layer including a light-scattering portion and a light-transmitting portion, where a surface roughness of the light-scattering portion is less than about 10 μm.

In an embodiment, a portion of the glass which is irradiated with the pulse laser may define the light-scattering portion.

In an embodiment, a portion of the glass which is not irradiated with the pulse laser may define the light-transmitting portion.

In an embodiment, a maximum diameter of fine fragments included in the light-scattering portion may be less than about 10 μm.

In an embodiment, a width of the light-scattering portion may be equal to a diameter of the beam of the pulse laser.

In an embodiment, a ratio of the width of the light-scattering portion to a height of the light-scattering portion may be about 1/100 or less.

In an embodiment, the light-scattering portion may be provided in plural, and a plurality of light-scattering portions may be arranged at regular intervals in a plan view.

In an embodiment, a ratio of a width of the light-transmitting portion to a sum of the width of the light-transmitting portion and the width of the light-scattering portion may be about 95% or greater.

In an embodiment, Light incident on the light-scattering portion may be Mie scattered by fine fragments included in the light-scattering portion.

In an embodiment, the glass may include silicon dioxide (SiO₂).

### BRIEF DESCRIPTION OF THE DRAWINGS

The above and other features of certain embodiments of the disclosure will be more apparent from the following description taken in conjunction with the accompanying drawings, in which:

FIG. 1 is a schematic perspective view of a display device according to an embodiment;

FIG. 2 is a schematic equivalent circuit diagram of one pixel according to an embodiment;

FIG. 3 is a schematic cross-sectional view taken along line A-A′ of the display device illustrated in FIG. 1;

FIG. 4 is a schematic cross-sectional view of a light control layer of a display device according to an embodiment;

FIG. 5 is a schematic enlarged view of area A of FIG. 4;

FIG. 6 is a schematic perspective view of an embodiment of a method of manufacturing a light control layer of a display device; and

FIG. 7 is a schematic cross-sectional view of a light control layer in the method of manufacturing the light control layer illustrated in FIG. 6.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. In addition, “at least one of A and B” or “at least one selected from A and B” indicates the case of A, B, or A and B. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

When a certain embodiment may be implemented differently, a specific process order may be performed differently from the described order. For example, two consecutively described processes may be performed substantially at the same time or performed in an order opposite to the described order.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

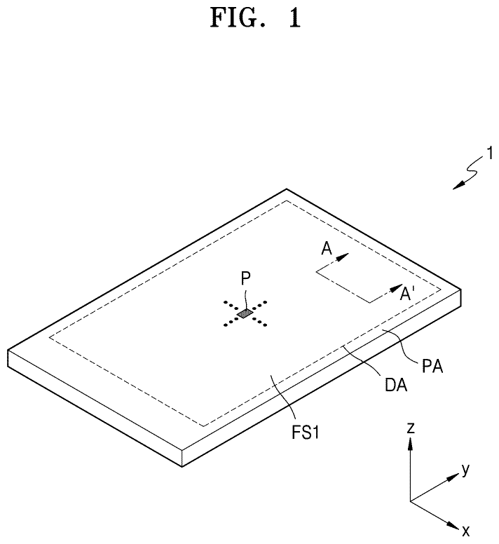

FIG. 1 is a schematic perspective view of a display device according to an embodiment.

Referring to FIG. 1, a display device 1 according to an embodiment may include a display area DA and a peripheral area PA. The peripheral area PA may be arranged to surround the display area DA on a periphery of the display area DA. The peripheral area PA may have various wiring and driving circuits that transmit electrical signals to be applied to the display area DA. The display device 1 may provide a predetermined image by using light emitted from a plurality of pixels arranged in the display area DA.

Hereinafter, embodiments where the display device 1 is an organic light-emitting display device will be described as an example, but a display device according to an embodiment is not limited thereto. The display device 1 may be any type of display device such as an organic light-emitting display, an inorganic light-emitting display, or a quantum dot light-emitting display.

The display device 1 may be implemented in various types of electronic devices, for example, mobile phones, smartphones, tablet personal computers (PC), mobile communication terminals, electronic organizers, electronic books, portable multimedia players (PMP), global positioning systems, or ultramobile PCs (UMPC). In an embodiment, the display device 1 may be a vehicle display device, for example, a dashboard of a vehicle, a center information display (CID) disposed on a center fascia or a dashboard of a vehicle, a room mirror display replacing a side-view mirror of a vehicle, and a display disposed on a rear surface of a front seat for entertainment in a back seat of a vehicle, but a display device according to an embodiment is not limited thereto.

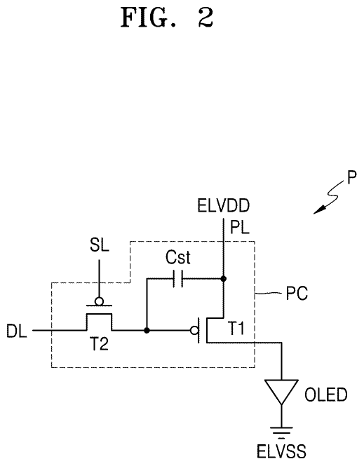

FIG. 2 is a schematic equivalent circuit diagram of one pixel according to an embodiment.

Referring to FIG. 2, in an embodiment of a pixel, an organic light-emitting diode OLED, which is a display element, may be connected to a pixel circuit PC. The pixel circuit PC may include a first thin-film transistor T1, a second thin-film transistor T2, and a storage capacitor Cst. The organic light-emitting diodes OLED may emit red, green, blue, or white light.

The second thin-film transistor T2 may be a switching thin-film transistor, connected to a scan line SL and a data line DL, and may transmit a data voltage input from the data line DL to the first thin-film transistor T1 based on a switching voltage input from the scan line SL. The storage capacitor Cst may be connected to the second thin-film transistor T2 and a driving voltage line PL, and may store a voltage corresponding to the difference between a voltage received from the second thin-film transistor T2 and a first power voltage ELVDD supplied to the driving voltage line PL.

The first thin film transistor T1 may be a driving thin film transistor, which is connected to the driving voltage line PL and the storage capacitor Cst, and may control a driving current flowing through the organic light-emitting diode OLED from the driving voltage line PL in response to a voltage value stored in the storage capacitor Cst. The organic light-emitting diode OLED may emit light with a certain brightness corresponding to the driving current. A counter electrode (e.g., a cathode) of the organic light-emitting diode OLED may be supplied with a second power voltage ELVSS.

Although FIG. 2 illustrates an embodiment where the pixel circuit PC includes two thin film transistors and one storage capacitor, it is to be understood that in other embodiments, the number of thin film transistors or the number of storage capacitors may vary depending on the design of the pixel circuit PC.

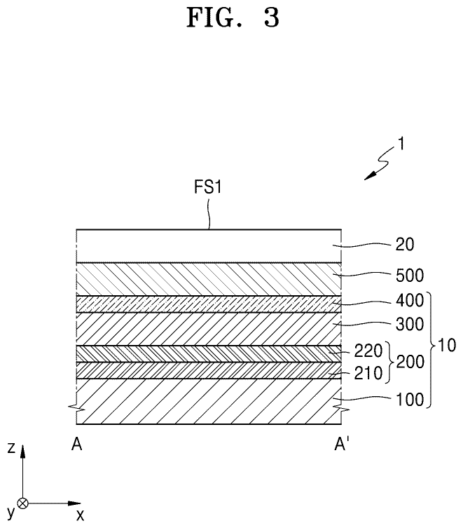

FIG. 3 is a schematic cross-sectional view taken along line A-A′ of the display device illustrated in FIG. 1.

Referring to FIG. 3, an embodiment of the display device 1 may include a display panel 10, a light control layer 500, and a cover window 20. The display panel 10 may include a substrate 100, a display layer 200, an encapsulation layer 300, and a touch sensor layer 400 sequentially laminated in a third direction (e.g., a z direction).

The substrate 100 may include a glass material or a polymer resin. In an embodiment, for example, the substrate 100 may include a glass material having silicon oxide (SiOₓ) as a main component, or may include a polymer resin such as polyethersulfone, polyarylate, polyetherimide, polyethylene naphthalate, polyethylene terephthalate, polyphenylene sulfide, polyimide, polycarbonate, cellulose triacetate, cellulose acetate propionate, etc.

The display layer 200 may be disposed on the substrate 100. The display layer 200 may include a pixel circuit layer 210 and a display element layer 220. The pixel circuit layer 210 may include a pixel circuit and a plurality of insulating layers including light-emitting diodes, and the display element layer 220 may include light-emitting diodes. The display element layer 220 may be arranged on the pixel circuit layer 210, and the plurality of insulating layers may be arranged between the pixel circuit and the light-emitting diodes. Some of wirings and the plurality of insulating layers of the pixel circuit layer 210 may extend to the peripheral area PA.

The encapsulation layer 300 may be disposed on the display layer 200. The encapsulation layer 300 may seal the light-emitting diodes included in the display element layer 220. In an embodiment, the encapsulation layer 300 may include at least one inorganic encapsulating layer and at least one organic encapsulating layer. The at least one inorganic encapsulating layer may include at least one selected from aluminum oxide (Al₂O₃), titanium oxide (TiO₂), tantalum oxide (Ta₂O₅), zinc oxide (ZnO), silicon oxide (SiOₓ), silicon nitride (SiNₓ), and silicon oxynitride (SiON). The at least one organic encapsulating layer may include a polymer-based material. The polymer-based material may include at least one selected from acrylic resin, epoxy resin, polyimide, and polyethylene. In an embodiment, the at least one organic encapsulating layer may include an acrylate.

The touch sensor layer 400 may be disposed on the encapsulation layer 300. The touch sensor layer 400 may be a layer that senses a user's touch input, and may detect the touch input using at least one of several touch methods, such as a resistive film method or an electrostatic capacitance method. In an embodiment, the touch sensor layer 400 may be disposed on an upper surface of the encapsulation layer 300 as shown in FIG. 2, but not being limited thereto. In another embodiment, the touch sensor layer 400 may also be disposed between the encapsulation layer 300 and the display layer 200. In an embodiment, the touch sensor layer 400 may be formed separately and attached to the encapsulation layer 300, or may be formed directly in a pattern shape on the encapsulation layer 300.

The light control layer 500 may be disposed on the touch sensor layer 400. The light control layer 500 may limit a viewing angle by scattering some of light emitted from the display element layer 220. In an embodiment, for example, the light control layer 500 may block light from various paths emitted from the display element layer 220 at an angle of about 45° or less with respect to a front surface FS1 of the display device 1. The light control layer 500 may be arranged in the display area DA. The light control layer 500 may include a transparent region via which light emitted from the light-emitting diodes arranged in the display area DA externally passes. In an embodiment, the light control layer 500 may be formed separately and attached to the display panel 10.

Although not shown, an anti-reflection layer, such as a polarizing layer or a color filter layer, may be disposed between the touch sensor layer 400 and the light control layer 500. The anti-reflection layer may partially absorb at least a portion of external light or internally reflected light.

The cover window 20 may be disposed on the display panel 10 and the light control layer 500. In an embodiment, the cover window 20 may be bonded to an underlying component, for example, the light control layer 500, via an adhesive such as an optically clear adhesive (OCA). The cover window 20 may protect the display panel 10 and the light control layer 500. The cover window 20 may include at least one selected from glass, sapphire, and plastic. The cover window 20 may be, for example, ultra-thin tempered glass (UTG) or colorless polyimide (CPI).

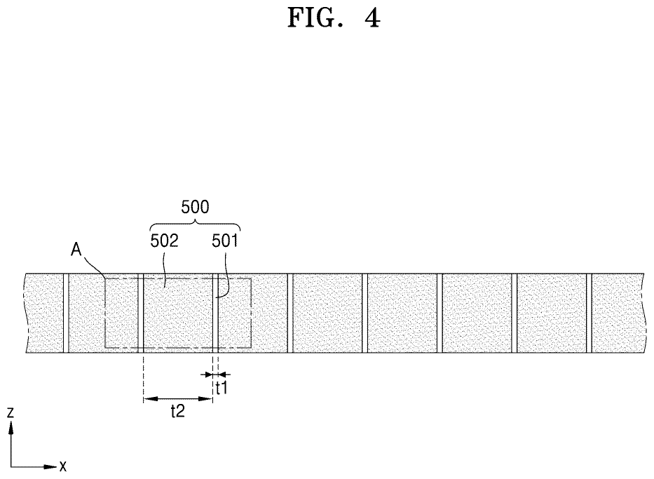

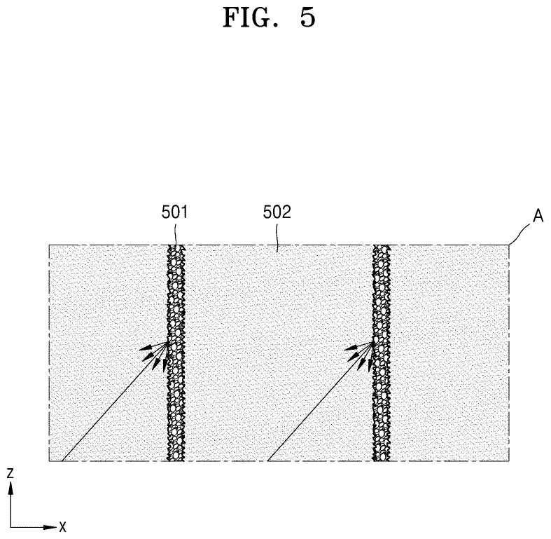

FIG. 4 is a schematic cross-sectional view of a light control layer of a display device according to an embodiment. FIG. 5 is a schematic enlarged view of area A of FIG. 4. Specifically, FIG. 5 schematically illustrates a process of light scattering when the light is incident on a light-scattering portion of a light control layer in an organic light-emitting diode.

Referring to FIGS. 4 and 5, in an embodiment, the light control layer 500 may include a light-transmitting portion 502 and the light-scattering portion 501. Specifically, the light control layer 500 may include a plurality of light-transmitting portions 502 and a plurality of light-scattering portions 501. The plurality of light-scattering portions 501 may be arranged at regular intervals in a plan view or when viewed in the z direction, which is a thickness direction of the light control layer 500. Specifically, the plurality of light-scattering portions 501 may be arranged at regular intervals in a first direction (e.g., in the x direction or the −x direction).

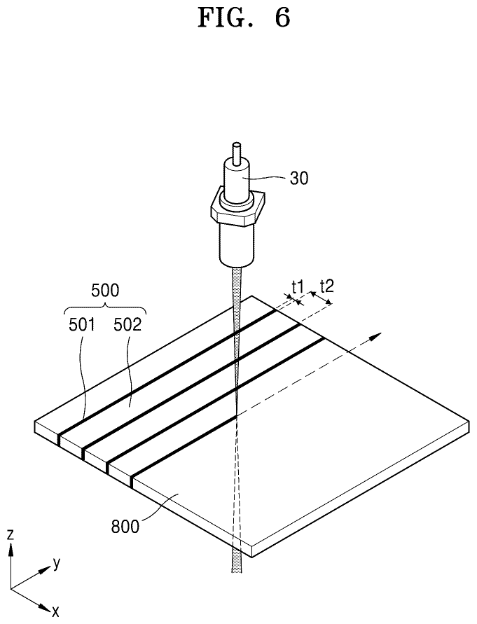

The light-scattering portion 501 may be formed by radiating a pulsed laser onto glass 800 (see FIG. 6) containing silicon dioxide (SiO₂). The light-scattering portion 501 may be a portion of the glass 800 where a pulse laser is radiated, and may contain fine fragments. Specifically, the light-scattering portion 501 may include a scattering center and an empty space capable of causing Mie scattering of incident light. A portion of the glass 800 that is not radiated with a pulse laser may define the light-transmitting portion 502. The light-transmitting portion 502 may include silicon dioxide (SiO₂).

Since the light-scattering portion 501 is formed by irradiation with a pulse laser, a width t1 of the light-scattering portion 501 may be equal to or substantially the same as the diameter of the beam of the pulse laser. The width t1 of the light-scattering portion 501 may be about 3 micrometers (μm) or less, and a width t2 of the light-transmitting portion 502 may be about 57 μm or greater. However, an embodiment of the disclosure is not limited thereto.

The ratio of the width t2 of the light-transmitting portion 502 to a sum of the width t2 of the light-transmitting portion 502 and the width t1 of the light-scattering portion 501 may be greater than or equal to about 95%. In other words, the transmittance of light emitted from the display element layer 220 (see FIG. 3) by the light control layer 500 may be greater than about 95%.

Because the light-scattering portion 501 of the light control layer 500 is formed by irradiation with a pulse laser, the light-scattering portion 501 may include fine fragments. A surface roughness of the light-scattering portion 501 may be less than about 10 μm. In an embodiment, for example, the surface roughness of the light-scattering portion 501 may be less than about 5 μm. The surface roughness of the light-scattering portion 501 may be measured by photographing the light-scattering portion 501 using a scanning electron microscope (SEM) or by scanning a surface of the light-scattering portion 501 using an atomic force microscope (AFM). In a sample section of the surface of the photographed light-scattering portion 501, the surface roughness of the light-scattering portion 501 may be measured by vertically measuring the distance from the highest point to the lowest point of the curve. In other words, the surface roughness of the light-scattering portion 501 may be a maximum height roughness of the surface of the light-scattering portion 501.

The surface roughness of the light-scattering portion 501 must be less than about 10 μm such that the fine fragments included in the light-scattering portion 501 act as scattering centers, and light incident from the display element layer 220 toward the light-scattering portion 501 may be Mie scattered. The light incident on the light-scattering portion 501 from the display element layer 220 is Mie scattered by the fine fragments included in the light-scattering portion 501 such that at least a portion of the light emitted from the display element layer 220 may not be emitted to the outside of the display device, and a viewing angle of the display device may be controlled.

In an embodiment, the surface roughness of the light-scattering portion 501 may be less than about 5 μm. In such an embodiment where the surface roughness of the light-scattering portion 501 is less than about 5 μm, the degree of Mie scattering of light incident on the light-scattering portion 501 may increase, and the degree to which the viewing angle of the display device is controlled may be improved.

In an embodiment, the maximum diameter of the fine fragments included in the light-scattering portion 501 may be less than about 10 μm. In an embodiment, for example, the maximum diameter of the fine fragments included in the light-scattering portion 501 may be less than about 5 μm.

In an embodiment, the maximum diameter of the fine fragments included in the light-scattering portion 501 is less than about 10 μm such that the fine fragments included in the light-scattering portion 501 act as scattering centers, and the light incident from the display element layer 220 toward the light-scattering portion 501 may be Mie scattered. The light incident on the light-scattering portion 501 from the display element layer 220 is Mie scattered by the fine fragments included in the light-scattering portion 501 such that at least a portion of the light emitted from the display element layer 220 may not be emitted to the outside of the display device, and the viewing angle of the display device may be controlled.

In an embodiment where the surface roughness of the light-scattering portion 501 is less than about 5 μm, the degree of Mie scattering of light incident toward the light-scattering portion 501 may increase, and the degree to which the viewing angle of the display device is controlled may be improved.

As a comparative example, a light-scattering portion may be formed by chemically etching at least a portion of glass containing silicon dioxide (SiO₂) and placing dye or metal particles in the space removed by the etching. For wet etching processes, a ratio of a width to a height of the etched portion may be to 1/10 or greater due to etching limitations. In this case, a height of the light-scattering portion is desired to be secured to control a viewing angle of the display device. However, when the light-scattering portion is formed through a wet etching process, if a height of the light-scattering portion is secured due to limitations of etching, a width of the light-scattering portion increases, thus shortening the width of the light-transmitting portion. Accordingly, light transmittance of the display device may not be secured. In other words, when etching glass to form the light-scattering portion by placing dye or metal particles in that portion, it may be impossible to control the viewing angle of the display device while simultaneously securing light transmittance.

In an embodiment, a pulse laser is radiated onto the glass to form the light-scattering portion 501 in a way such that the ratio of the width t1 of the light-scattering portion 501 to a height h1 of the light-scattering portion 501 may be secured to about 1/100 or less. In such an embodiment, by securing the height h1 of the light-scattering portion 501 while narrowing the width t1 of the light-scattering portion 501, the light transmittance of the display device may be secured while controlling the viewing angle of the display device.

In an embodiment, when the light-scattering portion 501 is formed by radiating a pulsed laser onto glass, the transmittance of light emitted from the display element layer 220 may be secured to be about 95% or greater, and at the same time, when the surface roughness of the light-scattering portion 501 formed by the pulsed laser is less than about 10 μm, light incident from the display element layer 220 toward the light-scattering portion 501 may be Mie scattered, thereby controlling the viewing angle of the display device.

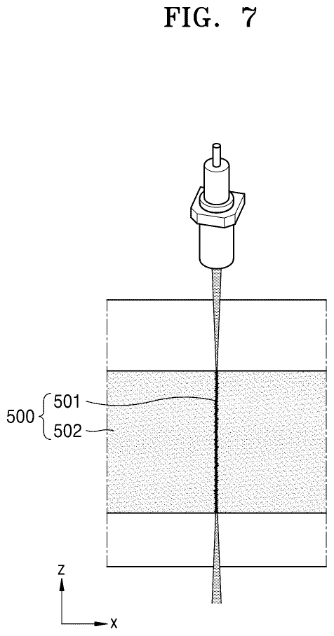

FIG. 6 is a schematic perspective view of an embodiment of a method of manufacturing a light control layer of a display device. FIG. 7 is a schematic cross-sectional view of a light control layer in the method of manufacturing the light control layer illustrated in FIG. 6.

Referring to FIGS. 6 and 7, an embodiment of a method of manufacturing the light control layer 500 of the display device may include preparing a glass 800, and irradiating the glass 800 with the pulse laser 30 to form the light control layer 500 including the light-scattering portion 501 and the light-transmitting portion 502. The glass 800 may include silicon dioxide (SiO₂).

The pulse laser 30 may scan the glass 800 in a second direction (e.g., the y direction or the −y direction). A portion of the glass 800 where the pulse laser 30 is radiated may form the light-scattering portion 501, and a portion of the glass 800 where the pulse laser 30 is not radiated may form the light-transmitting portion 502. The plurality of light-transmitting portions 502 and the plurality of light-scattering portions 501 may be formed by irradiating the glass 800 with the pulse laser 30 multiple times.

When irradiating the glass 800 with the pulse laser 30 multiple times, an interval between the pulse lasers 30 in the first direction (e.g., the x direction or the −x direction) may be constant. The light-scattering portions 501 formed by radiating a pulse laser 30 may be arranged at regular intervals in the first direction (e.g., x direction or −x direction).

Because the light-scattering portion 501 is formed by irradiating the glass 800 with the pulse laser 30, the diameter of the beam of the pulse laser 30 radiated on the glass 800 may be substantially the same as the width t1 of the light-scattering portion 501. The diameter of the beam of the pulse laser 30 radiated on the glass 800 may be about 3 μm or less, and the width t1 of the light-scattering portion 501 may be about 3 μm or less. The portion of the glass 800 that is not irradiated with the pulse laser 30 may define the light-transmitting portion 502. The width t2 of the light-transmitting portion 502 may be about 57 μm or greater. However, an embodiment of the disclosure is not limited thereto. The ratio of the width t2 of the light-transmitting portion 502 to the sum of the width t1 of the light-scattering portion 501 and the width t2 of the light-transmitting portion 502 may be about 95% or greater.

Because the light-scattering portion 501 is formed by irradiating the glass 800 with the pulse laser 30, the light-scattering portion 501 may include fine fragments. The diameters of the fine fragments included in the light-scattering portion 501 may be less than about 10 μm. In other words, the surface roughness of the light-scattering portion 501 may be less than about 10 μm. Additionally, the diameters of the fine fragments included in the light-scattering portion 501 may be less than about 5 μm. In other words, the surface roughness of the light-scattering portion 501 may be less than about 5 μm. The diameters of the fine fragments included in the light-scattering portion 501 must be less than about 10 μm (or less than about 5 μm) such that the fine fragments included in the light-scattering portion 501 act as scattering centers, and light incident on the light-scattering portion 501 may be Mie scattered. The light incident toward the light-scattering portion 501 in the display element layer 220 (see FIG. 3) may be Mie scattered by the fine fragments included in the light-scattering portion 501 and may not be emitted to the outside of the display device, and the viewing angle of the display device may be controlled.

Because the light-scattering portion 501 is formed by irradiating the glass 800 with the pulse laser 30, the ratio of the width t1 of the light-scattering portion 501 to the height h1 of the light-scattering portion 501 may be secured to about 1/100 or less. By securing the height h1 of the light-scattering portion 501 while narrowing the width t1 of the light-scattering portion 501, the light transmittance of the display device may be secured while controlling the viewing angle of the display device.

Because the fine fragments included in the light-scattering portion 501 formed by irradiation with the pulse laser 30 Mie-scatter the light incident toward the light-scattering portion 501 from the display element layer 220, the viewing angle of the display device is controlled while the width of the light-transmitting portion 502 is secured, and the transmittance of the light emitted from the display element layer 220 may be secured at about 95% or greater.

According to an embodiment as described above, a display device with improved reliability and quality and a method of manufacturing the display device can be implemented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate; and
a light control layer disposed on the substrate and including a light-scattering portion and a light-transmitting portion;
a surface roughness of the light-scattering portion is less than about 10 μm.

2. The display device of claim 1, wherein
the light-scattering portion is provided in plural.

3. The display device of claim 1, wherein
the light-transmitting portion is provided in plural.

4. The display device of claim 2, wherein
a plurality of light-scattering portions are arranged at regular intervals in a plan view.

5. The display device of claim 1, wherein
the light-transmitting portion includes silicon dioxide (SiO₂).

6. The display device of claim 1, wherein
a maximum diameter of fine fragments included in the light-scattering portion is less than 10 μm.

7. The display device of claim 1, wherein
the light-scattering portion is defined by a portion of a glass onto which a pulse laser is radiated, and
a width of the light-scattering portion is equal to a diameter of a beam of the pulse laser.

8. The display device of claim 1, wherein
a ratio of a width of the light-transmitting portion to a sum of the width of the light-transmitting portion and a width of the light-scattering portion is about 95% or greater.

9. The display device of claim 1, wherein
a ratio of a width of the light-scattering portion to a height of the light-scattering portion is about 1/100 or less.

10. The display device of claim 1, wherein
light incident on the light-scattering portion is Mie scattered by fine fragments included in the light-scattering portion.

11. A method of manufacturing of a display device, the method comprising:
preparing a glass; and
irradiating the glass with a pulse laser to form a light control layer including a light-scattering portion and a light-transmitting portion, wherein
a surface roughness of the light-scattering portion is less than about 10 μm, wherein
a portion of the glass which is irradiated with the pulse laser defines the light-scattering portion, wherein
a portion of the glass which is not irradiated with the pulse laser defines the light-transmitting portion.

12. The method of manufacturing of the display device of claim 11, wherein
a maximum diameter of fine fragments included in the light-scattering portion is less than about 10 μm.

13. The method of manufacturing of the display device of claim 11, wherein
a width of the light-scattering portion is equal to a diameter of a beam of the pulse laser.

14. The method of manufacturing of the display device of claim 11, wherein
a ratio of a width of the light-scattering portion to a height of the light-scattering portion is about 1/100 or less.

15. The method of manufacturing of the display device of claim 11, wherein
the light-scattering portion is provided in plural, and
a plurality of light-scattering portions are arranged at regular intervals in a plan view.

16. The method of manufacturing of the display device of claim 11, wherein
a ratio of a width of the light-transmitting portion to a sum of the width of the light-transmitting portion and a width of the light-scattering portion is about 95% or greater.

17. The method of manufacturing of the display device of claim 11, wherein
light incident on the light-scattering portion is Mie scattered by fine fragments included in the light-scattering portion.

18. The method of manufacturing of the display device of claim 11, wherein
the glass includes silicon dioxide (SiO₂).

19. An electronic device comprising:
a substrate; and
a light control layer disposed on the substrate and including a light-scattering portion and a light-transmitting portion;
a surface roughness of the light-scattering portion is less than about 10 μm.
